(19) United States
(12) Patent Application Publication
(10) Pub. No.: US 2026/0094986 A1
(43) Pub. Date: Apr. 2, 2026

(54) RIVET FOR USE IN SEMICONDUCTOR MODULE ARRANGEMENT AND METHOD FOR PRODUCING THE SAME

(71) Applicant: Infineon Technologies AG, Neubiberg (DE)

(72) Inventors: Balazs Kadar, Werstein Ot Allagen (DE); Regina Nottelmann, Lippetal (DE); Markus Ebers, Geseke (DE)

(73) Assignee: Infineon Technologies AG, Neubiberg (DE)

(21) Appl. No.: 19/332,985

(22) Filed: Sep. 18, 2025

(30) Foreign Application Priority Data
Sep. 27, 2024 (DE) 102024128082.4

(51) Int. Cl. H01R 12/71; H01R 43/02; H01R 43/20

(52) U.S. Cl. CPC H01R 12/718; H01R 43/0228; H01R 43/205

(57) ABSTRACT

A method for forming a rivet for a semiconductor module arrangement comprises providing a disc, the disc comprising a hole or depression, and inserting a first end of a tubular part into the hole or depression.

This application claims priority under 35 U.S.C § 119(b) to German patent application 102024128082.4, filed on Sep. 27, 2024.

### TECHNICAL FIELD

The instant disclosure relates to a rivet for use in a semiconductor module arrangement and to a method for producing such rivet.

### BACKGROUND

Power semiconductor module arrangements often include a base plate within a housing. At least one substrate is arranged on the base plate. A semiconductor arrangement including a plurality of controllable semiconductor elements (e.g., two IGBTs in a half-bridge configuration) is arranged on each of the at least one substrate. Each substrate usually comprises a substrate layer (e.g., a ceramic layer), a first metallization layer deposited on a first side of the substrate layer and, optionally, a second metallization layer deposited on a second side of the substrate layer. The controllable semiconductor elements are mounted, for example, on the first metallization layer. The second metallization layer is usually attached to the base plate by means of a solder layer or a sintering layer. The substrate and the semiconductor elements mounted thereon may be electrically coupled to the outside of the housing by means of terminal elements, for example. Such terminal elements may comprise or may be formed by a simple connection pin. In order to attach the terminal element to the substrate, a rivet may be permanently attached to the substrate, e.g., by means of a solder connection, and the connection pin may be inserted into the rivet such that the rivet fits over and encompasses a first end of the connection pin. A second end of the connection pin may protrude out of the housing such that the connection pin can be electrically contacted from the outside of the housing. A semiconductor module arrangement usually comprises a plurality of terminal elements.

There is a need for a method for producing rivets for semiconductor module arrangements easily and at low costs, resulting in reduced costs of the semiconductor module arrangement including such rivets.

### SUMMARY

A method for forming a rivet for a semiconductor module arrangement includes providing a disc, the disc including a hole or depression, and inserting a first end of a tubular part into the hole or depression.

A rivet for a semiconductor module arrangement includes a disc including a hole or depression, and a tubular part, wherein a first end of the tubular part is arranged inside the hole or depression.

The invention may be better understood with reference to the following drawings and the description. The components in the figures are not necessarily to scale, emphasis instead being placed upon illustrating the principles of the invention. Moreover, in the figures, like referenced numerals designate corresponding parts throughout the different views.

### BRIEF DESCRIPTION OF THE DRAWINGS

FIG. 1 is a cross-sectional view of a semiconductor module arrangement.

FIG. 2 schematically illustrates a three-dimensional view of a rivet during the assembly process according to embodiments of the disclosure.

FIG. 3 schematically illustrates a cross-sectional view of an assembled rivet according to embodiments of the disclosure.

FIG. 4 schematically illustrates a cross-sectional view of an assembled rivet according to further embodiments of the disclosure.

FIG. 5 schematically illustrates a bottom view of an assembled rivet according to embodiments of the disclosure.

FIG. 6 schematically illustrates a bottom view of an assembled rivet according to further embodiments of the disclosure.

FIG. 7 schematically illustrates a cross-sectional view of an assembled rivet according to further embodiments of the disclosure.

FIG. 8 schematically illustrates a cross-sectional view of an assembled rivet according to even further embodiments of the disclosure.

FIG. 9 schematically illustrates a cross-sectional view of an assembled rivet according to even further embodiments of the disclosure.

FIG. 10 schematically illustrates a three-dimensional view of a rivet during the assembly process according to further embodiments of the disclosure.

FIG. 11 schematically illustrates a cross-sectional view of an assembled rivet according to even further embodiments of the disclosure.

FIG. 12 schematically illustrates a cross-sectional view of an assembled rivet according to even further embodiments of the disclosure.

### DETAILED DESCRIPTION

In the following detailed description, reference is made to the accompanying drawings. The drawings show specific examples of how the invention can be implemented. It is to be understood that the features and principles described with respect to the various examples may be combined with each other, unless specifically noted otherwise. In the description, as well as in the claims, designations of certain elements as “first element”, “second element”, “third element” etc. are not to be understood as enumerative. Instead such designations serve solely to denote different “elements”. That is, e.g., the existence of a “third element” does not necessarily require the existence of a “first element” or a “second element”. An electrical line or electrical connection as described herein may be a single electrically conductive element, or include at least two individual electrically conductive elements connected in series and/or parallel. Electrical lines and electrical connections may include metal and/or semiconductor material and may be permanently electrically conductive (i.e., non-switchable). A semiconductor body as described herein may be made of (doped) semiconductor material and may be a semiconductor chip or be included in a semiconductor chip. A semiconductor body has electrically connectable pads and includes at least one semiconductor element with electrodes.

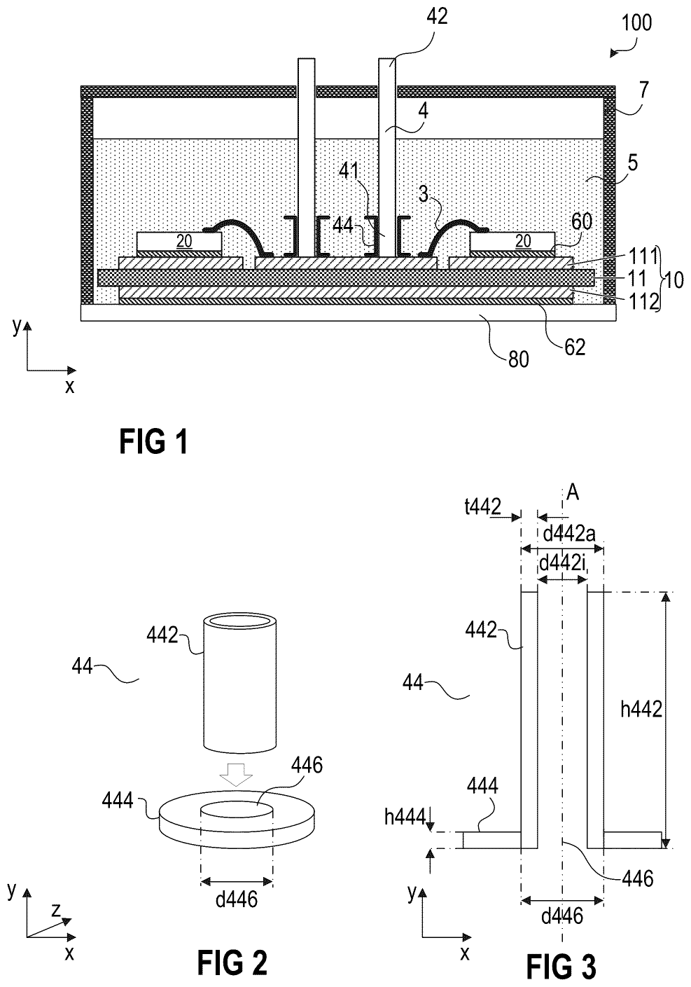

Referring to FIG. 1, a cross-sectional view of a semiconductor module arrangement 100 is illustrated. The semiconductor module arrangement 100 includes a housing 7 and a substrate 10. The substrate 10 includes a dielectric insulation layer 11, a (structured) first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. Alternatively, the dielectric insulation layer 11 may consist of an organic compound and include one or more of the following materials: Al₂O₃, AlN, SiC, BeO, BN, or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example. The material of the dielectric insulation layer 11 may be filled with ceramic particles, for example. Such particles may comprise, e.g., SiO₂, Al₂O₃, AlN, SiN or BN and may have a diameter of between about 1 μm and about 50 μm. The substrate 10 may also be a conventional printed circuit board (PCB) that has a non-ceramic dielectric insulation layer 11. For instance, a non-ceramic dielectric insulation layer 11 may consist of or include a cured resin.

The substrate 10 is arranged in a housing 7. In the example illustrated in FIG. 1, the substrate 10 is arranged on a base plate 80 which forms a base surface of the housing 7, while the housing 7 itself solely comprises sidewalls and (optionally) a cover. In some semiconductor module arrangements 100, more than one substrate 10 is arranged on the same base plate 80 and within the same housing 7. The base plate 80 may comprise a layer of a metallic material such as, e.g., copper or AlSiC. Other materials, however, are also possible. The base plate 80, however, may also be omitted. According to other examples, a substrate 10 itself may form a base surface of the housing 7. According to other examples, the housing 7 may comprise a base surface, sidewalls, and (optionally) a cover, and one or more substrates 10 may be arranged on the base surface provided by the housing 7.

One or more semiconductor bodies 20 may be arranged on the at least one substrate 10. Each of the semiconductor bodies 20 arranged on the at least one substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable semiconductor element.

The one or more semiconductor bodies 20 may form a semiconductor arrangement on the substrate 10. In FIG. 1, only two semiconductor bodies 20 are exemplarily illustrated. The second metallization layer 112 of the substrate 10 in FIG. 1 is a continuous layer. According to another example, the second metallization layer 112 may be a structured layer. According to other examples, the second metallization layer 112 may be omitted altogether. The first metallization layer 111 is a structured layer in the example illustrated in FIG. 1. “Structured layer” in this context means that the respective metallization layer is not a continuous layer, but includes recesses between different sections of the layer. Such recesses are schematically illustrated in FIG. 1. The first metallization layer 111 in this example includes three different sections. Different semiconductor bodies 20 may be mounted to the same or to different sections of the first metallization layer 111. Different sections of the first metallization layer may have no electrical connection or may be electrically connected to one or more other sections using electrical connections 3 such as, e.g., bonding wires. Semiconductor bodies 20 may be electrically connected to each other or to the first metallization layer 111 using electrical connections 3, for example. Electrical connections 3, instead of bonding wires, may also include bonding ribbons, connection plates or conductor rails, for example, to name just a few examples. The one or more semiconductor bodies 20 may be electrically and mechanically connected to the substrate 10 by electrically conductive connection layers 60. Such electrically conductive connection layers 60 may be solder layers, layers of an electrically conductive adhesive, or layers of a sintered metal powder, e.g., a sintered silver (Ag) powder, for example.

The semiconductor module arrangement 100 illustrated in FIG. 1 further includes terminal elements 4. The terminal elements 4 provide an electrical connection between the inside and the outside of the housing 7. The terminal elements 4 may be electrically connected to the first metallization layer 111 with a first end 41, while a second end 42 of the terminal elements 4 protrudes out of the housing 7. The terminal elements 4 may be electrically contacted from the outside at their second ends 42. Arranging the terminal elements 4 centrally on the substrate 10 is only an example. According to other examples, terminal elements 4 may be arranged closer to or adjacent to the sidewalls of the housing 7. The first end 41 of a terminal element 4 may be electrically and mechanically connected to the substrate 10 by means of a (hollow) rivet 44, as is illustrated in FIG. 1. The rivet 44 may be electrically and mechanically coupled to the first metallization layer 111 of the substrate 10 by means of an electrically conductive connection layer (not specifically illustrated in FIG. 1). Such an electrically conductive connection layer may be a solder layer, a layer of an electrically conductive adhesive, or a layer of a sintered metal powder, e.g., a sintered silver (Ag) powder, for example. The rivet 44 may comprise a tubular part, and the first end 41 of the terminal element 4 may be inserted into the tubular part of the rivet 44. The rivet 44, therefore, encloses the first end 41 of the terminal element 4, when the terminal element 4 is inserted in the rivet 44. The connection formed between the terminal element 4 and the rivet 44, therefore, may not be permanent, as the terminal element 4 may be easily removed from the rivet 44 without destroying the terminal element 4 and the rivet 44. However, the rivet 44 may fit tightly around the terminal element 4 so as to provide a stable electrical connection between the two parts.

The rivet 44, in addition to the tubular part, may further comprise at least one collar arranged at a first end of the tubular part and terminating the tubular part in the vertical direction y. The first end of the tubular part, when the rivet 44 is arranged on the substrate 10, faces towards the substrate 10 such that the collar is arranged on the first metallization layer 111. A dimension (e.g., radius or diameter) of such a collar in a horizontal direction (perpendicular to the vertical direction y) is generally larger than a dimension (e.g., thickness) of the tubular part in the same direction. The collar therefore increases the surface area of the rivet 44 and, consequently, the connecting surface between the rivet 44 and the substrate 10. This results in a much more stable connection between the rivet 44 and the substrate 10. In the example illustrated in FIG. 1, the rivets 44 further comprise a second collar at a second end of the rivets 44, the second end facing away from the substrate 10. The second collar, however, is not required for all applications and, therefore, is optional.

The semiconductor module arrangement 100 may further include an encapsulant 5. The encapsulant 5 may consist of or include a silicone gel or may be a rigid molding compound, for example. The encapsulant 5 may at least partly fill the interior of the housing 7, thereby covering the components and electrical connections that are arranged on the substrate 10. The terminal elements 4 may be partly embedded in the encapsulant 5. At least their second ends 42, however, are not covered by the encapsulant 5 and protrude from the encapsulant 5 through the housing 7 to the outside of the housing 7. The encapsulant 5 is configured to protect the components and electrical connections of the semiconductor module arrangement 100, in particular the components arranged inside the housing 7, from certain environmental conditions and mechanical damage. It is generally also possible to omit the housing 7 and solely protect the substrate 10 and any components mounted thereon with an encapsulant 5. In this case, the encapsulant 5 may be a rigid material, for example.

Semiconductor module arrangements often include several terminal elements 4. That is, a significant number of rivets 44 may be required to connect the terminal elements 4 to the substrate 10. Therefore, by reducing the costs for a single rivet 44, the overall costs for a semiconductor module arrangement may also be reduced. The costs for a rivet 44 can be reduced, for example, if the rivet 44 can be produced in a fast and efficient way. In the following, methods will be described that allow forming a rivet 44 for a semiconductor module arrangement 100 in a fast and efficient way and at low costs.

According to embodiments of the disclosure, a method for forming a rivet 44 for a semiconductor module arrangement according to embodiments of the disclosure comprises providing a disc 444, the disc 444 comprising a hole or depression 446, and inserting a first end of a tubular part 442 into the hole or depression 446. This is schematically illustrated in FIG. 2. Once the tubular part 442 has been inserted into the hole or depression 446 of the disc, the disc 444 forms a collar of the resulting rivet 44.

Known rivets are generally formed as a single piece and are often produced by means of, e.g., stamping or deep drawing processes. Such processes are often comparably complex, and the throughput is comparably low. The resulting rivets, therefore, are comparably expensive. When using the claimed method, two separate pieces are provided, namely a disc 444 and a tubular part 442. Both pieces can be produced separately at comparably low costs. The disc 444 and the tubular part 442 may subsequently be connected to each other using comparably simple tools. Even further, using the method described herein, a large number of rivets 44 can be manufactured in comparably short time. The process is simple, as the tubular part 442 merely needs to be inserted into the hole or depression 446 provided in the disc 444. This reduces the costs for each of the individual rivets 44 manufactured by means of the method described herein.

The disc 444 generally has a round shape. The same applies for the hole or depression 446 and the tubular part 442, which also generally have a round shape. The hole or depression 446 may be arranged centrally in the disc 444. That is, a center axis A of the hole or depression 446 may be identical with a center axis A of the disc 444. As is schematically illustrated in the cross-sectional view of FIG. 3, a diameter d442a of the tubular part 442 may equal a diameter d446 of the hole or depression 446 or may be up to 0.5 millimeters larger than the diameter d446 of the hole or depression 446. In this way, inserting the first end of the tubular part 442 into the hole or depression 446 results in a friction fit between the disc 444 and the tubular part 442. In some cases, no other connection than the friction fit may be required. In particular, the forces typically arising during assembly of a semiconductor module arrangement or during operation of a semiconductor module arrangement may be comparably low and may not be strong enough to remove the tubular part 442 from the disc 444 with the friction fit formed between the two elements. The diameter d442a of the tubular part 442 generally refers to an outer diameter. That is, the diameter d442a is the maximum diameter of the tubular part 442 and is defined by a diameter of the outer surface of the tubular part 442, the outer surface facing towards the disc 444, when the tubular part 442 has been inserted into the disc 444. The tubular part 442 generally also has an inner diameter d442i. The inner diameter d442i is a diameter of a hole extending through the tubular part 442 and is defined by a diameter of an inner surface of the tubular part 442, opposite the outer surface. A difference between the outer diameter d442a and the inner diameter d442i defines a wall thickness t442 of the tubular part 442.

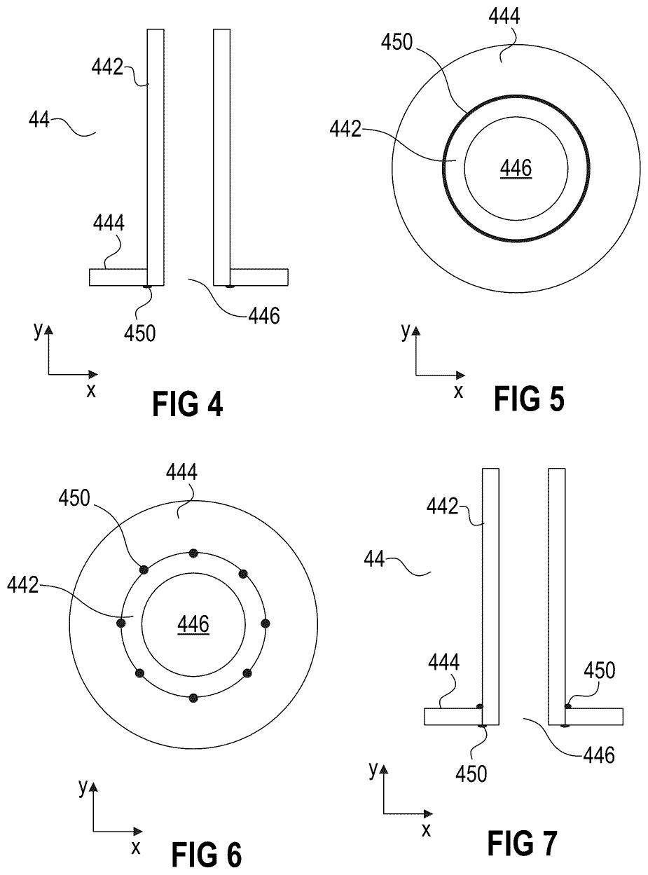

In some cases, a friction fit between the tubular part 442 and the disc 444 may not be sufficient. In such cases, the method may further comprise forming a welded connection 450 between the disc 444 and the tubular part 442. This is schematically illustrated in FIGS. 4 to 9. Referring to FIG. 4, the welded connection 450 may be formed on a bottom surface (or bottom side) of the disc 444 facing away from the tubular part 442. When the rivet 44 is arranged on a substrate 10, the bottom surface of the rivet 44 faces towards the substrate 10. Referring to FIG. 7, it is alternatively possible that the welded connection 450 is formed on a bottom surface of the disc 444 facing away from the tubular part 442 as well as on a top surface (or top side) of the disc 444 from which the tubular part 442 protrudes. The top surface is opposite the bottom surface. According to an even further example (not specifically illustrated), it is alternatively also possible that the welded connection 450 is only formed on the top surface of the disc 444 from which the tubular part 442 protrudes.

Referring to FIG. 5, forming a welded connection 450 between the disc 444 and the tubular part 442 may comprise forming a continuous weld seam along the entire circumference of the tubular part 442. The welded connection is indicated by means of a bold line in FIG. 5. A continuous weld seam, however, is not necessary for all applications. In some applications it may be sufficient that forming a welded connection 450 between the disc 444 and the tubular part 442 comprises forming at least two welding spots along the circumference of the tubular part 442. In the example illustrated in FIG. 6, eight welding spots are exemplarily illustrated. However, in some cases even two welding spots may be sufficient. The at least two welding spots may be evenly distributed along the diameter d442a of the tubular part 442.

As is exemplarily illustrated in FIGS. 3, 4 and 7, for example, inserting the first end of the tubular part 442 into the hole or depression 446 may comprise inserting the first end of the tubular part 442 from the top surface (or top side) of the disc 444 until the first end of the tubular part 442 (i.e. a bottom surface of the tubular part 442) is flush with the bottom surface of the disc 444. The bottom surface may be a surface of the disc 444 which, when the rivet 44 is fully assembled, faces away from the tubular part 442. This is generally only possible if the disc 444 comprises a hole 446 that extends all the way from the top surface of the disc 444 to the bottom surface.

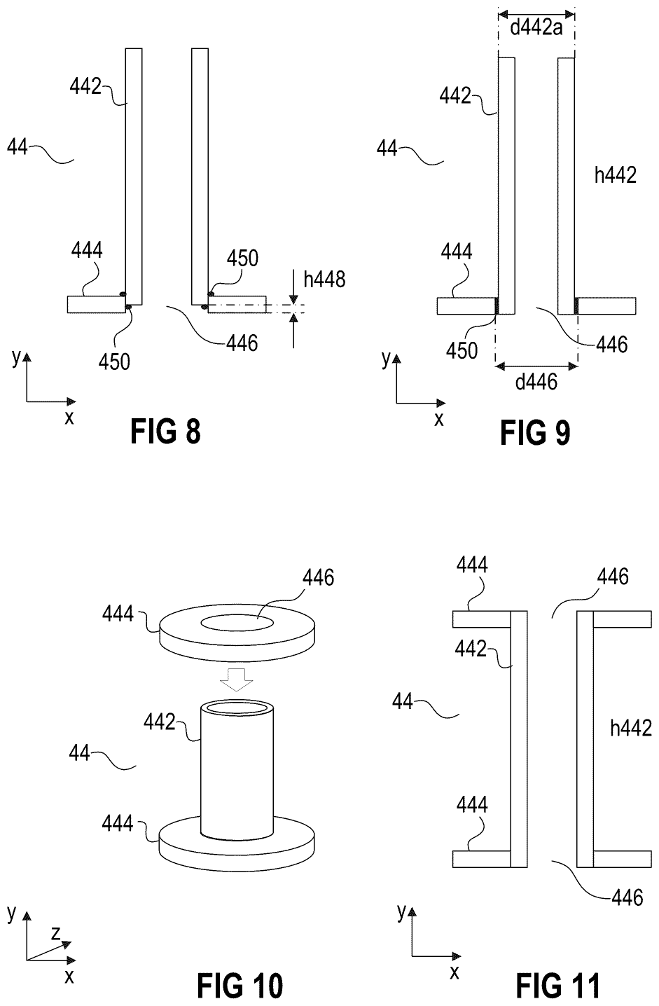

According to alternative embodiments, after inserting the first end of the tubular part 442 into the hole or depression 446 from the top side of the disc 444, the first end of the tubular part 442 may be arranged offset with respect to the bottom surface of the disc 444. That is, according to some examples, the tubular part 442 does not extend all the way from the top surface to the bottom surface of the disc 444. Instead, a cavity may remain between the tubular part 442 and the bottom surface of the disc 444. A height h448 of this cavity may be between 0 and 50% of the height h444 of the disc 444, for example. This is schematically illustrated in FIG. 8. Similar to what has been described above, the welded connection 450 may be formed on a bottom surface (or bottom side) of the tubular part 442. As the tubular part 442 in this example is not flush with the bottom surface of the disc 444, the welded connection 450 may be formed inside the hole 446. Additionally or alternatively the welded connection 450 may be formed on a top surface (or top side) of the disc 444 from which the tubular part 442 protrudes, similar to what has been disclosed above. If the tubular part 442 is not flush with the bottom surface of the disc 444, a welded connection 450 may be formed on a bottom side of the tubular part 442 without resulting in elevations on the bottom surface of the disc 444, as the welded connection 450 in this case is formed inside the hole or depression 446. That is, the bottom surface of the disc 444, and therefore of the resulting rivet 44 remains flat and even.

Referring to FIG. 9, it is also possible that a welded connection 450 be formed (horizontally) between the disc 444 and the tubular part 442. This applies for rivets 44 where the tubular part 442 is flush with the bottom surface of the disc 444 (see, e.g., FIGS. 3, 4, 7), as well as for rivets 44 where the tubular part 442 is not flush with the bottom surface of the disc 444 (see, e.g., FIG. 8). If a welded connection 450 is formed (horizontally) between the disc 444 and the tubular part 442, an outer diameter d442a of the tubular part 442 may be somewhat smaller than the diameter d446 of the hole or depression 446. For example, the outer diameter d442a of the tubular part 442 may be between 0.5 and 1 mm smaller than the diameter d446 of the hole or depression 446.

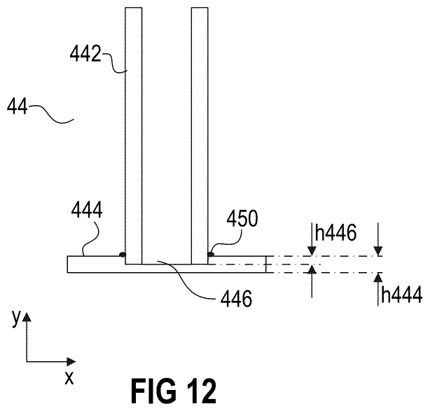

In the examples illustrated in FIGS. 3 to 9, the disc comprises a hole 446 extending from the top surface of the disc 444 through the disc 444 to the bottom surface of the disc 444. That is, a height h446 of the hole 446 equals a height h444 of the disc 444. It is, however, also possible, to provide a disc 444 comprising a depression 446 formed therein, as is schematically illustrated in FIG. 12. The depression 446 extends from the top surface into the disc 444, wherein the height h446 of the depression 446 is less than the height h444 of the disc 444. When the tubular part 442 has been inserted into the depression 446, the resulting rivet 44 has a closed bottom end. That is, when the rivet 44 is, e.g., soldered to a substrate 10 of a semiconductor module arrangement 100, no solder may enter into the tubular part 442, which may be desirable for some applications. If the disc 444 comprises a depression 446, the bottom end of the tubular part 442 that is arranged inside the depression 446 is not accessible from the bottom surface of the disc 444. Therefore, a welded connection 450 (if any) may only be formed on a top surface of the disc 444.

In the examples illustrated in FIGS. 2 to 9 and 12, the resulting rivet 44 comprises one collar on a bottom side thereof, the collar being formed by the disc 444 attached to the tubular part 442. Using rivets 44 with only one collar may be sufficient for many applications. Some applications, however, may require rivets 44 comprising two collars on opposite sides thereof. The method, therefore, may further comprise providing a second disc 444, the second disc 444 comprising a hole 446, and inserting a second end of the tubular part 442 into the hole 446, wherein the second end of the tubular part 442 is opposite the first end. This is schematically illustrated in FIG. 10. All that has been said with respect to the disc 444 and the tubular part 442 above, similarly applies for the second disc 444 and the tubular part 442 as illustrated in FIG. 10. By inserting the second end of the tubular part 442 into the hole 446 of the second disc 444, a rivet 44 comprising two collars on opposite ends may be easily formed. A cross-sectional view of a resulting rivet 44 is exemplarily illustrated in FIG. 11.

While the disc 444 attached to the first end of the tubular part 442 may comprise a hole or a depression 446, the second disc 444 may comprise a hole 446. In this way, the second end of the tubular part 442 remains open even when the second disc 444 is attached thereto such that a terminal element 4 may be inserted into the tubular part 442 from the second end. If the disc 444 attached to the first end of the tubular part 442 comprises a hole 446, it is generally also possible that the second disc 444 comprises a depression 446. In this case, the second disc 444 may be attached to a substrate 10 of a semiconductor module arrangement 100. A terminal element 4 may then be inserted into the tubular part 442 from its first side. That is, if a rivet 44 comprises two discs 444, at least one of the discs 444 comprises a hole 446, while the other disc may comprise a hole or depression 446. It is, however, of no relevance which disc 444 is attached to the tubular part 442 first. In any case, at least one side of the tubular part 442 remains open when both discs 444 are attached thereto.

A disc 444 may generally be formed in any suitable way, e.g., stamping out of sheet material. A disc 444 may then be held in a desired position while a tubular part 442 is inserted into the disc 444 by means of a suitable tool such as a simple gripping tool, for example. According to even further examples, it is even possible that a disc 444 is attached to a substrate 10 of a semiconductor module arrangement 100 first, and a tubular part 442 is inserted into the hole or depression 446 of the disc 444 by means of a suitable tool only after the disc 444 has been attached to the substrate 10.

The described method allows to produce rivets 44 for semiconductor module arrangements 100 in a very easy and effective way, and at low costs. With the claimed method, it is also possible to produce rivets 44 fulfilling many different requirements. A rivet 44 for a semiconductor module arrangement 100 according to embodiments of the disclosure comprises a disc 444 comprising a hole or depression 446, and a tubular part 442, wherein a first end of the tubular part 442 is arranged inside the hole or depression 446.

According to some embodiments, the disc 444 consists of a first material, and the tubular part 442 consists of a second material that is different from the first material. In this way, the disc 444 and the tubular part 442 may comprise different properties and characteristics, thereby fulfilling different requirements. For example, the material of the disc 444 may be suitable to be easily welded or soldered to a substrate 10 of a semiconductor module arrangement 100. The tubular part 442, however, for some applications may be required to fulfill different requirements. For example, the first material and the second material may comprise a different hardness, different thermal conductivity and/or different electrical conductivity. The first material and the second material alternatively or additionally may have other properties that differ from each other.

The rivet 44 according to embodiments of the disclosure may comprise a disc 444 comprising a bottom surface on a first side and a top surface on a second side opposite the first side, wherein the tubular part 442 protrudes from the second side of the disc 444, and wherein a distance between the bottom surface and the top surface defines a height h444 of the disc 444 in a vertical direction y. The rivet 44 may further comprise a tubular part 442 which, in a horizontal plane, perpendicular to the vertical direction y, has an outer diameter d442a and an inner diameter d442i, the outer diameter d442a and the inner diameter d442i defining a wall thickness t442 of the tubular part 442, wherein the height h444 of the disc differs from the wall thickness t442 of the tubular part.

In rivets 44 produced by means of conventional methods, a height of the collar (corresponding to height h444 of disc 444) generally is the same as a thickness t442 of the tubular part. For some applications, however, rivets 44 may be required or advantageous wherein the height h444 of the disc 444 differs from the wall thickness t442 of the tubular part 442. Such rivets generally cannot be (easily) produced with conventional methods. However, as the method as described herein attaches two separate parts (disc 444 and tubular part 442) to each other, any requirements concerning a height h444 of the disc 444 and a thickness t442 of the tubular part 442 may be easily met, as the parts are produced independent from each other and are only subsequently assembled to form the rivet 44.

As has been described above, the rivet 44 may further comprise a welded connection 450 between the disc 444 and the tubular part 442. According to further embodiments, and as has been described above, the rivet 44 may further comprise a second disc 444 comprising a hole 446, wherein a second end of the tubular part 442 opposite the first end is arranged inside the hole 446.

A semiconductor module arrangement according to embodiments of the disclosure comprises a substrate 10 comprising a dielectric insulation layer 11 and a metallization layer 111 arranged on a first side of the dielectric insulation layer 11, and one or more rivets 44 according to embodiments of the disclosure attached to the metallization layer 111.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A method for forming a rivet for a semiconductor module arrangement comprising:
providing a disc, the disc comprising a hole or depression; and
inserting a first end of a tubular part into the hole or depression.

2. The method of claim 1, wherein an outer diameter of the tubular part equals a diameter of the hole or depression or is up to 0.5 millimeters larger than the diameter of the hole or depression, and inserting the first end of a tubular part into the hole or depression results in a friction fit between the disc and the tubular part.

3. The method of claim 1, further comprising forming a welded connection between the disc and the tubular part.

4. The method of claim 3, wherein forming a welded connection between the disc and the tubular part comprises forming at least two welding spots along the circumference of the tubular part.

5. The method of claim 3, wherein forming a welded connection between the disc and the tubular part comprises forming a continuous weld seam along the circumference of the tubular part.

6. The method of claim 3, wherein the welded connection is formed on a bottom surface of the disc facing away from the tubular part and/or on a top surface of the disc from which the tubular part protrudes.

7. The method of claim 1, wherein inserting the first end of the tubular part into the hole or depression comprises inserting the first end of the tubular part from a top surface until the tubular part is flush with a bottom surface of the disc opposite the top surface.

8. The method of claim 1, wherein, after inserting the first end of the tubular part into the hole or depression, the first end of the tubular part is arranged offset with respect to a bottom surface of the disc which faces away from the tubular part.

9. The method of claim 1, further comprising
providing a second disc, the second disc comprising a hole; and
inserting a second end of the tubular part into the hole, wherein the second end of the tubular part is opposite the first end.

10. A rivet for a semiconductor module arrangement, the rivet comprising
a disc comprising a hole or depression; and
a tubular part, wherein a first end of the tubular part is arranged inside the hole or depression.

11. The rivet of claim 10, wherein the disc consists of a first material, and the tubular part consists of a second material that is different from the first material.

12. The rivet of claim 10 or 11, wherein
the disc comprises a bottom surface on a first side and a top surface on a second side opposite the first side, wherein the tubular part protrudes from the second side of the disc, and wherein a distance between the bottom surface and the top surface defines a height of the disc in a vertical direction,
the tubular part, in a horizontal plane perpendicular to the vertical direction, has an outer diameter and an inner diameter, the outer diameter and the inner diameter defining a wall thickness of the tubular part, and
the height of the disc differs from the wall thickness of the tubular part.

13. The rivet of claim 10, further comprising a welded connection between the disc and the tubular part.

14. The rivet of claim 10, further comprising a second disc comprising a hole, wherein a second end of the tubular part opposite the first end is arranged inside the hole.

15. A semiconductor module arrangement comprising:
a substrate comprising a dielectric insulation layer and a metallization layer arranged on a first side of the dielectric insulation layer; and
one or more rivets comprising:
a disc (444) comprising a hole or depression (446); and
a tubular part (442), wherein a first end of the tubular part (442) is arranged inside the hole or depression (446).
